(19) United States
(12) Patent Application Publication
(10) Pub. No.: US 2009/0212400 A1
(43) Pub. Date: Aug. 27, 2009

(54) SEMICONDUCTOR DEVICE AND MANUFACTURING METHOD AND MOUNTING METHOD THEREOF

(76) Inventor: Yasuhide HARA, Kyoto (JP)

Correspondence Address: MCDERMOTT WILL & EMERY LLP, 600 13TH STREET, NW, WASHINGTON, DC, 20005-3096, US

(21) Appl. No.: 12/238,978

(22) Filed: Sep. 26, 2008

(30) Foreign Application Priority Data
Feb. 25, 2008 (JP) 2008-043213

(51) Int. Cl. H01L 21/50; H01L 23/538

(52) U.S. Cl. 257/621; 438/121; 438/113; 257/E23.174; 257/E21.499

(57) ABSTRACT

A semiconductor device includes: a semiconductor substrate having an active region on a surface thereof; at least one electrode pad provided in a peripheral portion of the surface of the semiconductor substrate; and a through electrode extending through the semiconductor substrate and connected to the electrode pad. A taper is provided on at least one side of the semiconductor substrate, whereby a portion of the through electrode which is exposed to a side of the semiconductor substrate serves as an external electrode.

### CROSS REFERENCE TO RELATED APPLICATION

This application claims priority under 35 U.S.C. §119 on Patent Application No. 2008-043213 filed in Japan on Feb. 25, 2008, the entire contents of which are hereby incorporated by reference.

### BACKGROUND OF THE INVENTION

1. Field of the Invention

The invention relates to a semiconductor device and a manufacturing method and a mounting method thereof. More particularly, the invention relates to reduction in thickness of a chip size package.

2. Related Art

With recent reduction in thickness of electronic equipments, there has been a growing demand for higher density mounting of semiconductor devices. Moreover, with improvement in integration degree of semiconductor devices due to the progress of fine processing technology, a so-called chip mounting technology of directly mounting a chip size package or a bare-chip semiconductor device has been proposed.

The same trend applies to optical devices having a semiconductor device, and various structures have been proposed in the industry. Among those structures, a typical example of a semiconductor device capable of semiconductor waver level mounting will now be described.

FIGS. 8A through 8E are cross-sectional views showing a method for manufacturing a semiconductor device 102 in a conventional example. As shown in FIG. 8A, a semiconductor wafer 140 including a plurality of semiconductor devices 102 in a surface thereof is first prepared. The semiconductor device 102 has an active region 111 at a surface thereof and has electrode pads 112 provided in a peripheral portion thereof.

As shown in FIG. 8B, through holes 104 are first formed corresponding to the electrode pads 112 of each semiconductor device 102 included in the semiconductor wafer 140. The through holes 104 extend from the back surface of the semiconductor wafer 140 through the semiconductor devices 102. The through holes 104 are micro holes having a diameter of 10 μm to 120 μm and are formed by etching.

As shown in FIG. 8C, the through holes 104 thus formed are filled with a conductive material 105 to form a filled via structure. A conductor pattern 106 is formed on the bottom surface of the semiconductor devices 102 so as to electrically connect to the electrode pads 112 on the front surface of the semiconductor devices 102 through the filled via structure. Note that, instead of filling the through holes 104 with the conductive material 105, the conductor pattern 106 electrically connected to the electrode pads 112 on the front surface of the semiconductor devices 102 can be formed on the bottom surface of the semiconductor devices 102 by performing metal plating on the inner walls of the through holes 104.

As shown in FIG. 8D, the semiconductor wafer 140 is finally divided into individual semiconductor devices 102 by using a dicing blade 117. As shown in FIG. 8E, a chip-like semiconductor device 102 having its front and back surfaces connected to each other through the through holes 104 can thus be obtained.

Instead of this typical semiconductor wafer level, electrode pads may be formed on the back surface of the semiconductor wafer 140 without forming the through electrodes in the semiconductor wafer 140. An example of this technology is disclosed in Japanese Laid-Open Patent Publication No. 2003-17621, which will now be described with reference to FIGS. 9A through 9D.

According to this technology, as shown in FIG. 9A, a semiconductor wafer 140 is first prepared. The semiconductor wafer 140 includes a plurality of semiconductor devices 102 each including an active region 111 and electrode pads 112 on the front surface thereof. A wiring pattern 122 made of a conductor layer is then formed on the back surface of each semiconductor device 102.

As shown in FIG. 9B, the front surface of the semiconductor wafer 140 is then cut in a dividing region between the plurality of semiconductor devices 102 by using a V-shaped dicing blade 114 to form a V-shaped groove portion 115.

As shown in FIG. 9C, the semiconductor wafer 140 is then cut along the V-shaped groove 115 by using a dicing blade 117. The semiconductor wafer 140 is thus divided into individual semiconductor devices 102.

A conductor layer 118 is then formed on the side surface of each divided semiconductor device 102. The electrode pads 112 on the front surface of the semiconductor device 102 are connected with the wiring pattern 122 on the back surface thereof through the conductor layer 118.

External electrodes of the semiconductor device 102 can also be exposed to the back surface of the semiconductor wafer 140 by such a method.

A structure of a conventional semiconductor device mounted on a substrate will now be described. FIG. 10 is a cross-sectional view showing a state of the conventional semiconductor device 102 shown in FIG. 8E mounted on a substrate 130. As shown in FIG. 10, the conductor pattern 106 provided on the back surface of the semiconductor device 102 and a conductor pattern 107 provided on a surface of the substrate 130 are connected to each other through solder bumps 108 or the like. The electrode pads 112 of the semiconductor device 102 and the substrate 130 are thus electrically connected to each other through the conductive material 105 embedded in the through holes.

In such a mounting method using the through electrodes, the height from the surface of the substrate 130 to the top end of the semiconductor device 102 (height H in FIG. 10) needs to be at least the thickness of the semiconductor device 102 plus about 80 μm.

More specifically, the conductor pattern 106 provided on the back surface of the semiconductor device 102 needs to have a thickness of about 10 μm to about 20 μm, the conductor pattern 107 provided on the substrate 130 needs to have a thickness of about 50 μm, and the solder bumps 108 connecting the conductor patterns 106 and 107 to each other needs to have a thickness of about 20 μm to about 30 μm. The sum of these thicknesses is 80 μm to 100 μm.

Note that, before the method using the through electrodes was used, the electrode pads 12 provided on the front surface of the semiconductor device 102 used to be connected to the conductor pattern provided on the substrate 130 through gold wires. In this case, the height of at least about 100 μm is required from the top surface of the semiconductor device 102.

In the mounting method using the through electrodes, the required height is lower (the thickness of the semiconductor device plus about 80 μm to about 100 μm, as described above) and more stable than that in the method using the gold wires.

### SUMMARY OF THE INVENTION

However, the thickness of semiconductor devices has been reduced to as thin as about 150 μm to about 300 μm in recent years. The height of about 80 μm to about 100 μm required to mount a semiconductor device has occupied a large proportion of the mounting height of the semiconductor device. Accordingly, there has been a demand for a mounting method of a semiconductor device capable of reducing the mounting height. It is an object of the invention to implement such a mounting method of a semiconductor device.

When the semiconductor device 102 is an optical device such as a CCD (Charge Coupled Device), not only reduction in the mounting height on the substrate 130 but a mounting parallelism between the semiconductor device 102 and the substrate 310 are important (when the semiconductor device 102 is tilted with respect to the substrate 130, the height from the top surface of the substrate 130 to the bottom surface of the semiconductor device 102 varies depending on the position; such a difference in height is called a parallelism). More specifically, in the case of an optical device, this parallelism needs to be 10 μm or less.

When mounting is performed by using the through electrodes and the solder bumps 108 as shown in FIG. 10, it is possible to obtain a parallelism of 10 μm or less between the semiconductor device 102 and the substrate 130. However, if the substrate 130 having the semiconductor device 102 mounted thereon is used as a module and secondarily mounted on another substrate, the parallelism may degrade to more than 10 μm. Such degradation in parallelism is caused by the following reason: heat generated by the secondary mounting softens the solder that serves as an electric connection material and a material for fixing the semiconductor device 102 to the substrate 130 and also curves the substrate 130. Such curving of the substrate 130 causes stress, whereby the solder itself is deformed and the semiconductor device 102 is tilted.

A typical method to prevent such degradation in parallelism is to inject an underfill between the semiconductor device 102 and the substrate 130 and cure the underfill. The step of injecting the underfill, however, is the step of injecting a resin in a gap of about 40 μm to about 100 μm between the substrate 130 and the semiconductor device 102. It is therefore necessary to accurately ground a dispense nozzle and fill the gap with the underfill material by penetration using capillarity. Adding such an underfill step increases the manufacturing cost and manufacturing time.

In view of the above problems, there has been a demand for a simpler mounting method of a semiconductor device capable of maintaining a required parallelism. It is another object of the invention to implement such a mounting method of a semiconductor device.

The invention made by the inventors of the present application in view of the above problems will now be described. In other words, a semiconductor device capable of reducing the mounting height of a semiconductor device mounted on a substrate and capable of easily assuring a mounting parallelism between the semiconductor device and the substrate, and a manufacturing method and mounting method of the semiconductor device will now be described.

A semiconductor device according to the invention includes: a semiconductor substrate having an active region on a surface thereof; at least one electrode pad provided in a peripheral portion of the surface of the semiconductor substrate; and a through electrode extending through the semiconductor substrate and connected to the electrode pad. A taper is provided on at least one side of the semiconductor substrate, whereby a portion of the through electrode which is exposed to a side of the semiconductor substrate serves as an external electrode.

Preferably, the taper provided on at least one side of the semiconductor substrate has a cutting surface formed by cutting the peripheral portion from a back surface thereof, and the through electrode extends from the electrode pad to the cutting surface, and a portion of the through electrode which is exposed to the cutting surface serves as the external electrode.

A method for mounting the semiconductor device of the invention on a mounting substrate according to the invention includes the steps of: fixing a back surface of the semiconductor device to the mounting substrate; and electrically connecting the external electrode exposed to a side of the semiconductor device with a substrate electrode provided on the mounting substrate.

In the semiconductor device and the mounting method thereof according to the invention, mounting can be performed by fixing the back surface of the semiconductor device to the mounting substrate by an adhesive material or the like. Moreover, a portion of the through electrode is exposed to the side of the semiconductor device by cutting the peripheral portion of the back surface, and this portion serves as the external electrode. Electric connection between the semiconductor device and the mounting substrate can thus be obtained by using the external electrode.

When a conventional semiconductor device is mounted, respective electrodes of the semiconductor device and a mounting substrate, solder bumps for connecting the electrodes, and the like are interposed between the semiconductor device and the mounting substrate. According to the invention, the mounting height of the semiconductor device mounted on the mounting substrate can be reduced as compared to the conventional structure.

Moreover, in a conventional mounting method using solder bumps, the mounting parallelism may be degraded by thermal deformation of the solder bumps or the like. According to the invention, on the other hand, the back surface of the semiconductor device is fixed on the mounting substrate by an adhesive or the like. Degradation in parallelism can therefore be avoided. Moreover, mounting can be easily performed with a high parallelism.

In the mounting method of the semiconductor device according to the invention, it is preferable that the substrate electrode has an elastic property.

This increases an alignment margin in mounting of the semiconductor device. In other words, even if misalignment occurs in mounting, the elastic substrate electrode is deformed and electric connection between the semiconductor device and the mounting substrate is assured if the misalignment is relatively small. As a result, mounting can be performed well even if the alignment accuracy is lower than that in the case where the substrate electrode does not have an elastic property.

In the semiconductor device of the invention, it is preferable that a projection made of a conductive material is provided on the external electrode.

In the mounting method of the semiconductor device according to the invention, it is preferable that an electrode projection that is smaller than the external electrode of the semiconductor device is provided on the substrate electrode, and the substrate electrode and the through electrode are electrically connected to each other through the electrode projection.

This structure enables improvement in positional accuracy in mounting the semiconductor device on the mounting substrate and more reliably ensures electric connection between the semiconductor device and the mounting substrate.

A method for manufacturing a semiconductor device according to the invention includes the steps of: (a) preparing a semiconductor wafer having a plurality of chip regions that are to be diced into individual semiconductor devices; (b) in each of the plurality of chip regions, providing at least one electrode pad on a peripheral portion of a surface having an active region and providing a through electrode extending from a back surface of the semiconductor wafer to the electrode pad; (c) after the step (b), cutting a peripheral portion of the back surface in each of the plurality of chip regions to expose the through electrode to a side of the chip region so that the exposed portion serves as an external electrode; and (d) after the step (c), the plurality of chip regions are diced into individual semiconductor devices.

In the manufacturing method of the semiconductor device according to the invention, the semiconductor device of the invention, that is, the semiconductor device in which the through electrode is exposed to the cutting surface formed by cutting the peripheral portion of the back surface and the exposed portion serves as an external electrode, can be manufactured. The effects of such a semiconductor device and a mounting method thereof are described above.

In the manufacturing method of the semiconductor device according to the invention, it is preferable that the step (c) is performed by forming, in a portion including a dividing line between adjacent chip regions, a groove portion having a V-shaped cross section from the back surface of the semiconductor wafer, and the dicing is performed along the groove portion in the step (d).

This enables cutting to be performed simultaneously on the peripheral portions of adjacent two chip regions. Moreover, the cutting surface can be easily provided as a tilted surface that is less than vertical to the back surface of the semiconductor device.

Preferably, the manufacturing method of the semiconductor device according to the invention further includes the step of, after the step (c), providing a projection made of a conductive material on the external electrode.

This enables manufacturing of a semiconductor device having a projection on the external electrode. The effects of such a semiconductor device and a mounting method thereof are described above.

In the semiconductor device and the manufacturing method and mounting method thereof according to the invention, the back surface of the semiconductor device is fixed to the mounting surface without interposing electrodes, solder bumps, and the like therebetween, whereby the mounting height of the semiconductor device mounted on the mounting substrate can be reduced as compared to a conventional example. Moreover, the parallelism of the semiconductor device to the mounting substrate can be easily improved, and degradation of the parallelism can be prevented. The invention is therefore useful as an optical device and a camera module, and can be used to reduce the thickness and cost of a digital still camera, a digital video camera, a portable camera module, other camera modules, and the like.

### BRIEF DESCRIPTION OF THE DRAWINGS

FIGS. 1A, 1B, 1C, and 1D show a semiconductor device according to a first embodiment of the invention, wherein FIG. 1A is a plan view, FIG. 1B is a cross-sectional view taken along line Ib-Ib′ in FIG. 1A, FIG. 1C is a side view, and FIG. 1D is a bottom view;

FIGS. 2A and 2B are diagrams illustrating a manufacturing process of a semiconductor device according to the first embodiment of the invention, and respectively show the front and back surfaces of a semiconductor wafer including chip regions that are to be divided into individual semiconductor devices;

FIGS. 3A, 3B, 3C, 3D, 3E, and 3F are diagrams illustrating a process of manufacturing an individual semiconductor device according to the first embodiment of the invention by processing the semiconductor wafer;

FIGS. 4A, 4B, 4C, and 4D are diagrams illustrating a process of mounting a semiconductor device on a mounting substrate according to the first embodiment of the invention;

FIGS. 5A, 5B, 5C, 5D, 5E, and 5F are diagrams illustrating a manufacturing method of a semiconductor device according to a modification of the first embodiment of the invention;

FIG. 6A is a diagram illustrating a second embodiment of the invention and shows a state of a semiconductor device mounted on a mounting substrate, and FIG. 6B is a partial enlarged view of FIG. 6A;

FIG. 7A is a diagram illustrating a third embodiment of the invention and shows a state of a semiconductor device mounted on a mounting substrate, and FIG. 7B is a partial enlarged view of FIG. 7A;

FIGS. 8A, 8B, 8C, 8D, and 8E are diagrams illustrating a semiconductor device and a manufacturing method thereof according to a related art;

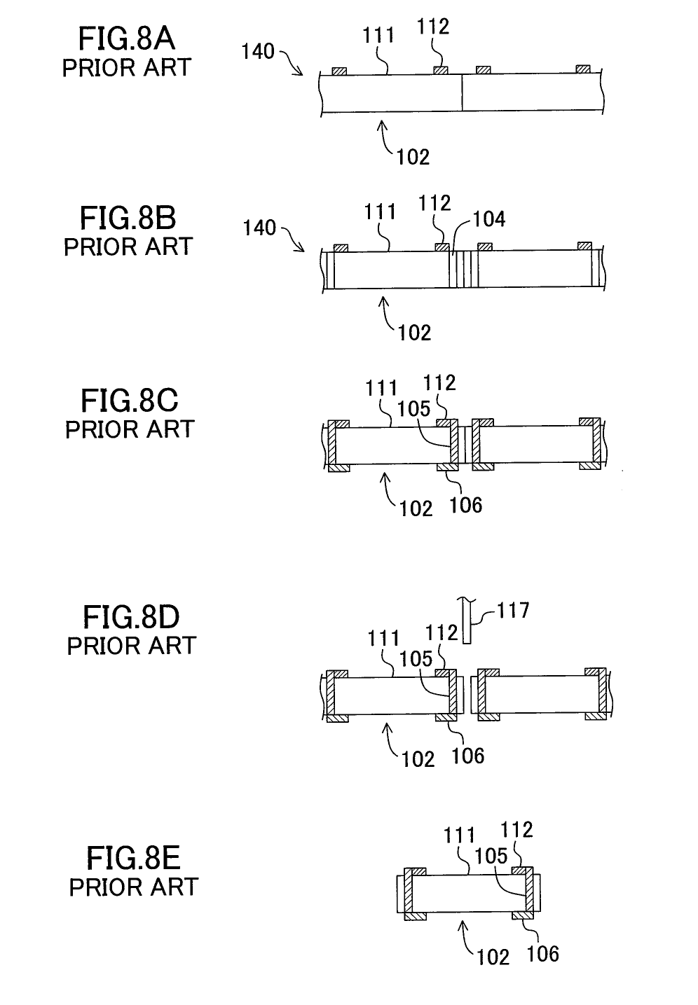

FIGS. 9A, 9B, 9C, and 9D are diagrams illustrating a semiconductor device and a manufacturing method thereof according to another related art; and

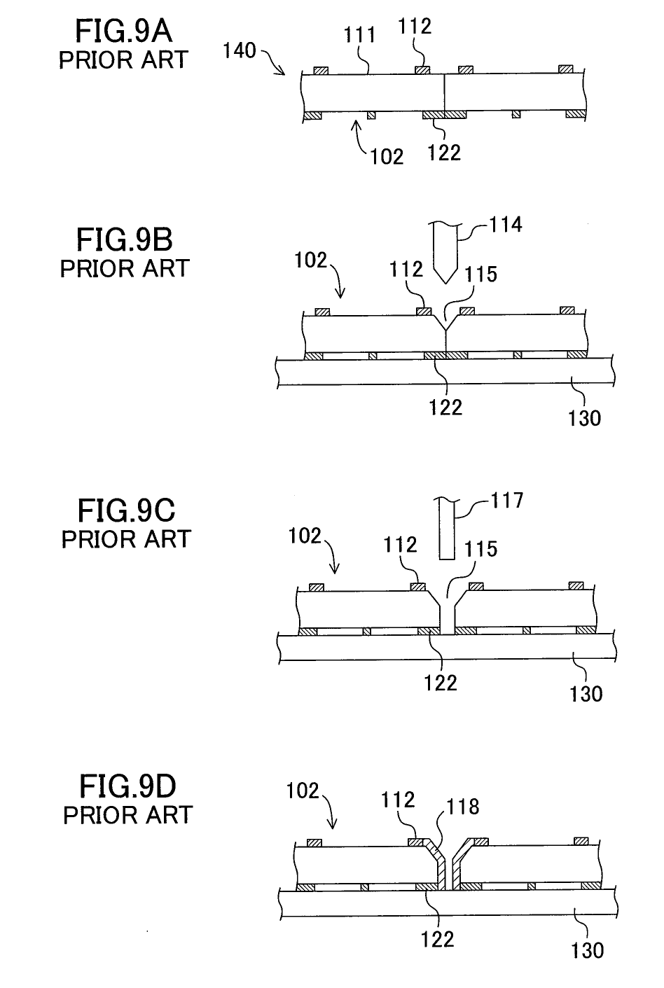

FIG. 10 is a diagram illustrating a mounting method of a semiconductor device and a mounting height according to a related art.

### DETAILED DESCRIPTION OF THE PREFERRED EMBODIMENTS

Hereinafter, embodiments of the invention will be described with reference to the accompanying drawings. Note that the figures that are herein referred to are drawn schematically and the dimensions shown in the figures do not correspond to an actual shape. In the following embodiments, a solid-state imaging device, which is an optical device for which the mounting parallelism is particularly important, is described as an example of a semiconductor device. Specific examples of the solid-state imaging device include devices that are used in a camera module, a cellular phone, a digital still camera, and a medical endoscope, and the like. However, the semiconductor device is not limited to an optical device, and the contents of each embodiment are applicable also to a system LSI (Large Scale Integration) and the like.

### First Embodiment

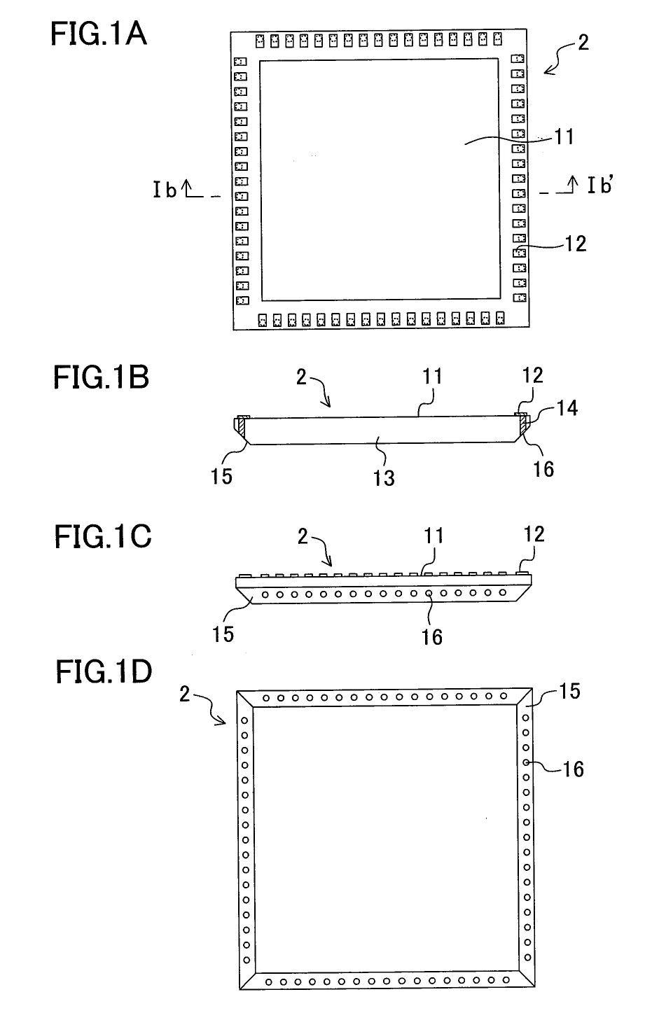

FIGS. 1A through 1D are diagrams showing a semiconductor device 2 according to a first embodiment. FIG. 1A is a plan view showing the semiconductor device 2 viewed from the front surface thereof, FIG. 1B is a cross-sectional view taken along line Ib-Ib′ in FIG. 1A, FIG. 1C is a side view, and FIG. 1D is a bottom view of the semiconductor device 2 viewed from the back surface thereof. As described above, in this embodiment, a solid-state imaging device is described as an example of the semiconductor device 2.

As shown in FIGS. 1A through 1D, the semiconductor device 2 of this embodiment is formed by using a semiconductor substrate 13 made of silicon. The semiconductor device 2 has an active region 11 on a surface thereof and electrode pads 12 on a peripheral portion of the surface. (As shown particularly in FIG. 1B), through holes are formed in the semiconductor substrate 13 so as to extend from the back surface of the semiconductor substrate 13 to the electrode pads 12. Through electrodes 14 are formed by embedding a conductive material in the through holes. A cutting surface 15 is formed by cutting the peripheral portion in the back surface of the semiconductor substrate 13. The through electrodes 14 are thus exposed to the cutting surface 15, and the exposed portions of the through electrodes 14 function as external electrodes 16.

Note that an electric circuit provided in the active region 11 is electrically connected to the electrode pads 12, whereby an electric path is formed from the external electrodes 16 to the electric circuit.

The above components will now be described in more detail.

The through holes extending through the semiconductor substrate 13 are micro holes having a diameter of about 20 μm to about 120 μm. The through holes need only extend through the semiconductor substrate 13 from the back surface to the front surface thereof, and the through electrodes 14 formed by embedding a conductive material in the through holes need only contact the electrode pads 12 formed on the surface of the semiconductor substrate 13. In other words, the through holes may extend only through the semiconductor substrate 13 and the through electrodes 14 may contact the bottom surface of the electrode pads 12, respectively. Alternatively, the through holes may further extend into the electrode pads 12 by removing a part of the respective electrode pads 12 or may further extend through the electrode pads 12b, and the through electrodes 14 and the electrode pads 12 may contact each other by embedding a conductive material in the whole length of the through holes.

The through electrodes 14 have a filled via structure formed by filling the through holes with a conductive material such as copper (Cu). Instead of this structure, however, an electric connection to the electrode pads 12 may be obtained by performing metal plating such as gold (Au) or Cu on the inner walls of the through holes.

Such through electrodes 14 are exposed to the cutting surface 15 that is a surface tilted with respect to the back surface of the semiconductor substrate 13 by cutting the peripheral edge along the four sides of the back surface of the semiconductor substrate 13. The respective exposed surfaces of the through electrodes 14 function as the external electrodes 16. As described above, the through holes have a diameter of about 20 μm to about 120 μm. The external electrodes 16 at the cutting surface 15 therefore also have a diameter of about 20 μm to about 120 μm.

When the semiconductor device 2 having the above structure is mounted onto a mounting substrate, the height from the surface of the mounting substrate to the top surface of the semiconductor device (mounting height) can be lowered as compared to a conventional example. This will be described in further detail later.

Hereinafter, a manufacturing method of the semiconductor device 2 will be described.

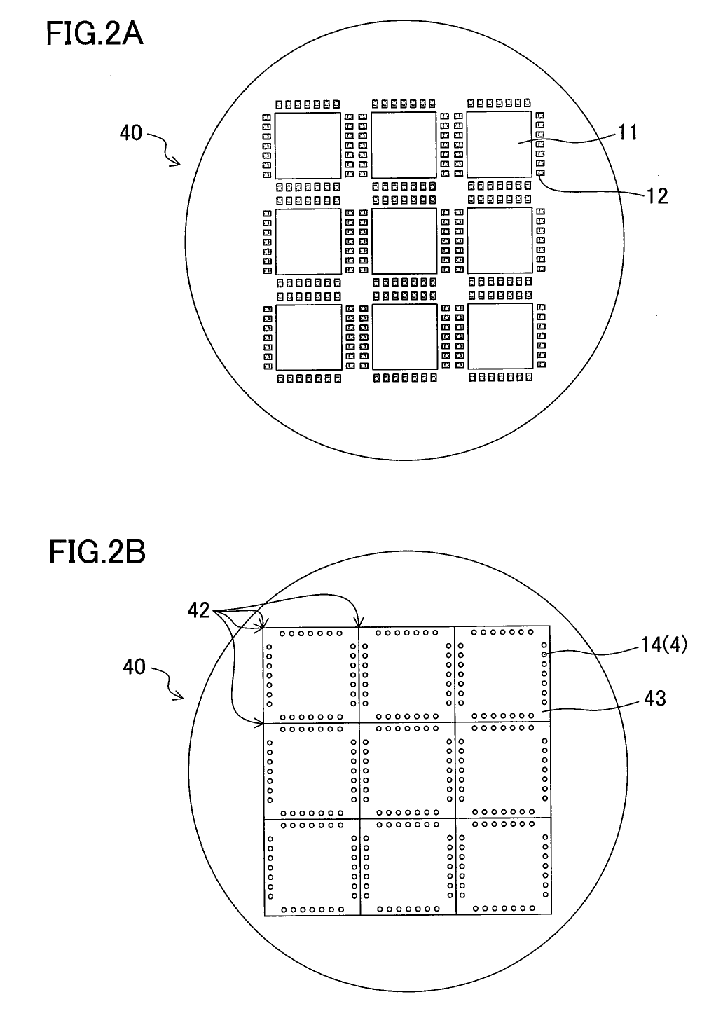

FIGS. 2A and 2B are diagrams respectively showing the front and back surfaces of a semiconductor wafer that is used to manufacture the semiconductor device 2. As shown in FIG. 2B, a semiconductor wafer 40 has a plurality of chip regions 43 that are to be divided along a dividing line 42 into individual chips as semiconductor devices. The semiconductor wafer 40 may be made of silicon or a compound semiconductor such as germanium arsenide (GeAs).

As shown in FIG. 2A, each chip region 43 has at the front surface thereof an active region 11 having various elements and the like. Electrode pads 12 are provided in a peripheral portion of the front surface. Through holes 4 are formed by etching, laser, or the like so as to extend through the semiconductor wafer 40 from the back surface thereof to the electrode pads 12.

The through holes 4 have a diameter of about 20 μm to about 120 μm and are formed so as to extend to the electrode pads 12 or to extend into the electrode pads 12 from the respective back surfaces of the electrode pads 12. The dimensions (diameter in this example) of the through electrodes 14 and the external electrodes 16 are determined by the thickness of the semiconductor wafer 40 used to form the semiconductor device 2 and the size and pitch of the electrode pads 12 on the surface of the semiconductor device 2. More specifically, in a typical example, the thickness of the semiconductor wafer 40 is about 200 μm to about 650 μm, the width of the electrode pads 12 is about 50 μm to about 150 μm, and the pitch of the electrode pads 12 is about 60 μm to about 200 μm. The diameter of the through electrodes 14 is desirably set to 40% to 80% of the width of the electrode pads 12. The diameter of the through holes 14 and the external electrodes 16 is therefore about 20 μm to about 120 μm.

In this case, when the positional accuracy and the diameter processing accuracy in formation of the through holes 4 are within ±10%, there will be no impact on adjacent electrode pads 12.

The through holes 4 thus formed are then filled with a conductive material such as Cu to form the through electrodes 14 having a filled via structure. Instead of filling the through holes 4 with a conductive material, the through electrodes 14 may alternatively be formed by performing metal plating such as Au or Cu on the inner walls of the through holes 4.

The step of forming the through electrodes 14 in the state of the semiconductor wafer 40 in order to electrically extend the electrode pads 12 of the semiconductor device 2 to the back surface of the semiconductor device 2 is thus completed.

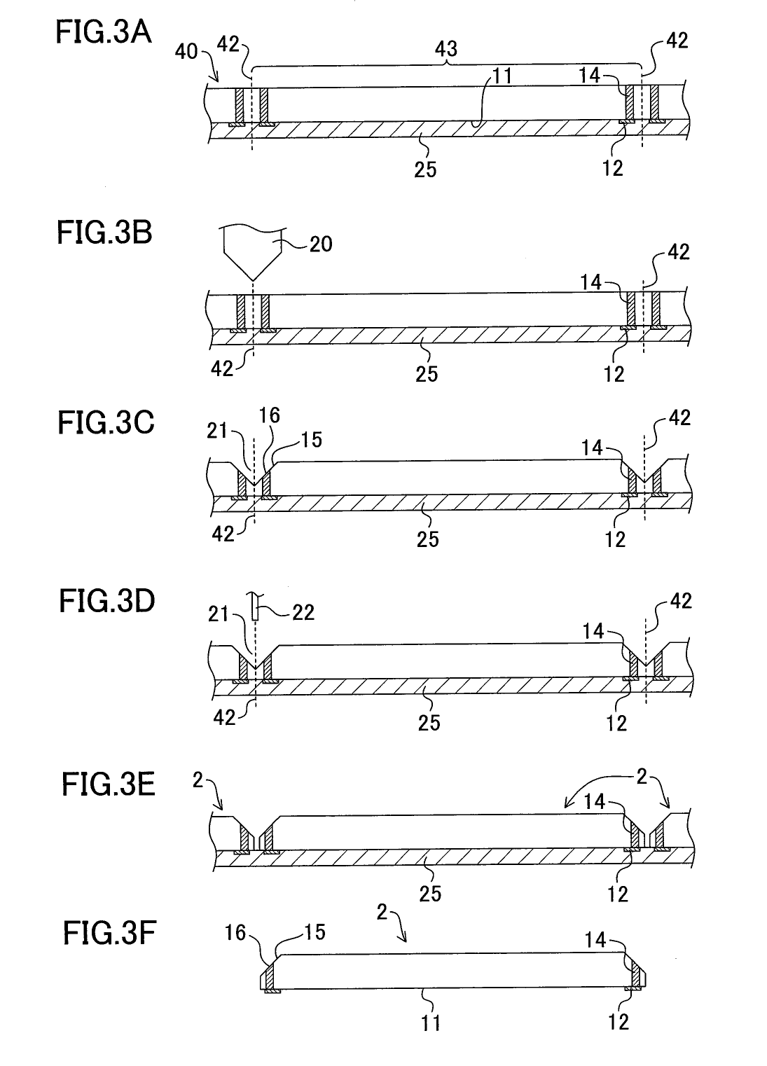

Hereinafter, the step of exposing the through electrodes 14 to the side of the semiconductor device 2 and the step of dividing the semiconductor wafer 40 into individual chips will be described. FIGS. 3A through 3F are cross-sectional views illustrating these steps.

As shown in FIG. 3A, a dicing sheet 25 to be used for dicing is first attached to the front surface (the surface on which the active region 11 and the electrode pads 12 are provided) of the semiconductor wafer 40 after the steps described above. Note that FIGS. 3A through 3F show in an enlarged view one of the plurality of chip regions 43 to be divided along a dividing line 42 into individual semiconductor devices.

As shown in FIG. 3B, in a region including the dividing line 42 between the chip regions 43, cutting is performed from the back side of the semiconductor wafer 40 by using a dicing blade 20 (first cutting). A diving blade having a V-shaped tip is herein used as the dicing blade 20. The peripheral portion of the chip region 43 in which the through electrodes 43 are formed is cut in this step.

FIG. 3C shows the state after the cutting is completed. When viewed as the semiconductor wafer 40, a groove portion 21 having a V-shaped cross section is formed along the dividing line 42 by the cutting. When viewed as individual chip regions 43, a corner along the four sides of the peripheral portion of the back surface of each chip region 43 is cut to form a cutting surface 15 that is tilted with respect to the back surface. The cutting surface 15 thus formed can be regarded as a sidewall of the groove portion 21. The through electrodes 14 are exposed to the cutting surface 15, and the exposed parts of the through electrodes 14 function as external electrodes 16.

Note that the cutting surface 15 typically forms an angle of 30° to 60° with the back surface of the semiconductor wafer 40. However, the point is that the through electrodes 14 are exposed to the cutting surface 15, and the angle is not limited to 30° to 60°.

As an example of the dimensions, the thickness of the semiconductor wafer 40 is about 300 μm, and the distance from the dividing line 42 to the through electrodes 14 is about 50 μm to about 150 μm. When dicing is performed by using a blade having a normal width of about 30 μm, the cutting width is about 50 μm including the influence of eccentricity of the blade. Therefore, the distance (pitch) between the through electrodes 14 included in adjacent chip regions 43 and facing each other with the dividing line 42 interposed therebetween may be about 150 μm to about 300 μm, that is, two times about 50 μm to about 150 μm plus the cutting width of about 50 μm.

Dicing is performed by using the dicing blade 20 having a tip angle of 90°. This enables the processing of forming the cutting surface 15 and thus exposing the through electrodes 14 to be performed simultaneously on the chip regions 43 of two adjacent rows. The chip regions 43 of two adjacent rows may also be simultaneously processed by changing the width and tip angle of the dicing blade 20.

In the above example, the V-shaped dicing blade 20 is used to form the cutting surface 15 as a tapered surface (a surface tilted with respect to the back surface of the semiconductor wafer 40) and the external electrodes 16 are formed on the cutting surface 15. However, the invention is not limited to this. For example, a U-shaped dicing blade may be used to form an R-curved cutting surface 15 and the through electrode 14 may be exposed to the R-curved surface as the external electrodes 16. Alternatively, cutting may be performed in a direction vertical to the back surface of the semiconductor wafer 40 so that the through electrodes 14 are exposed to the side of the chip regions 43 as the external electrodes 16. In this case, the cutting surface 15 extends vertically to the back surface of the semiconductor wafer 40.

As shown in FIG. 3D, cutting is then performed again on the groove portion 21 by using a dicing blade 22 having a narrower width than that of the dicing blade 20 (second cutting). As a result, as shown in FIG. 3E, the semiconductor wafer 40 is divided into individual chip regions 43 as semiconductor devices 2.

Thereafter, as shown in FIG. 3F, the semiconductor devices 2 are peeled from the dicing sheet 25, whereby individual semiconductor devices 2 are obtained.

Dicing of a semiconductor wafer is typically performed with the back surface of a semiconductor wafer attached to a dicing sheet. Moreover, cutting is typically performed by optically recognizing a scribe lane between chip regions. Therefore, if a protective material such as glass is attached to the front surface of the semiconductor wafer, light refraction caused by glass or the like may result in displacement of a recognized position of the dividing line. Moreover, if the material such as glass is opaque, optical positional detection itself may become impossible.

In this embodiment, however, dicing is performed with the front surface of the semiconductor wafer 40 (the surface having the active region 11) attached to the dicing sheet 25. In this case, the dividing line 42 between the chip regions 43 can be detected on the back surface of the semiconductor wafer 40 by using the through electrodes 14 as a recognition target, whereby cutting can be performed with high accuracy. Moreover, after the cutting is completed, cutting accuracy may be detected by recognizing the respective positions of the cutting end and the through electrodes 14.

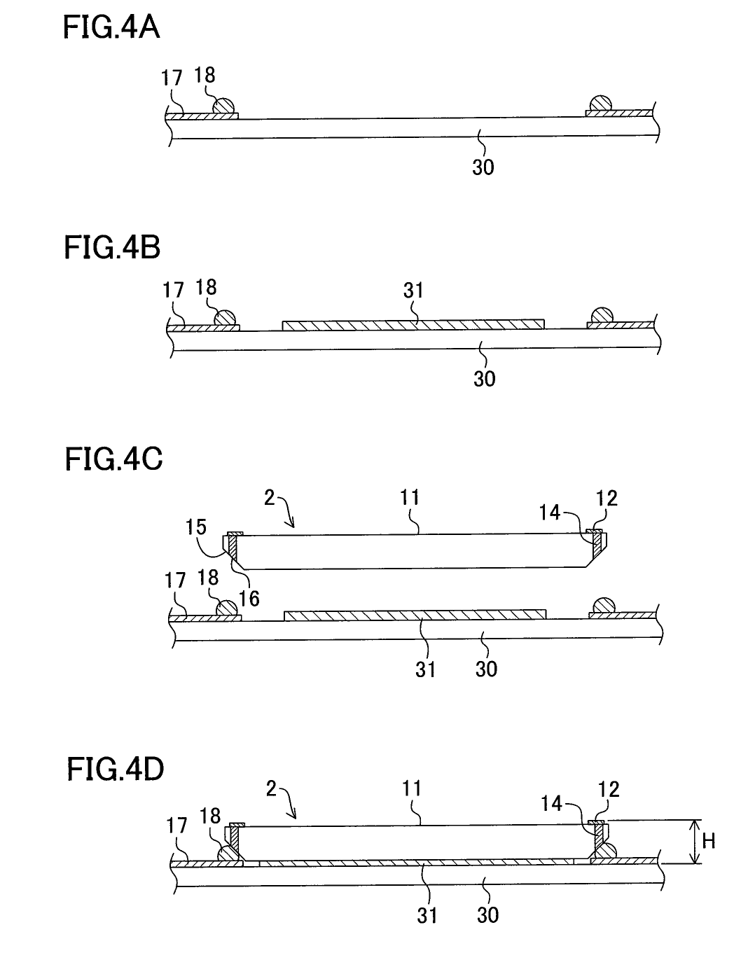

Hereinafter, a mounting method of the semiconductor device 2 will be described. FIGS. 4A through 4D are diagrams illustrating a mounting method of the semiconductor device 2. Solder balls 18 are used in the example described below.

FIG. 4A is a cross-sectional view of a mounting substrate 30 for mounting the semiconductor device 2. An electrode pattern 17 for obtaining electric connection with the semiconductor device 2 is formed on the mounting substrate 30. The solder balls 18 are formed on the electrode pattern 17.

An example of a method for forming the solder balls 18 is to mount the solder balls 18 after applying a flux to the electrode pattern 17. It is also common to transfer a solder paste onto the electrode pattern 17 by screen printing. The solder balls 18 may be formed by any method.

As shown in FIG. 4B, an adhesive material 31 (for example, an epoxy thermosetting resin) is then applied to a region where the semiconductor device 2 is to be mounted on the mounting substrate 30. The mounting substrate 30 is then heated to a curing temperature of the adhesive material 31 (about 100° C. to about 150° C.) and the semiconductor device 2 is placed on the mounting substrate 30 (FIG. 4C). Since the melting point of the solder balls 18 (typically 220° C. to 265° C.) is higher than the curing temperature of the adhesive material 31, the semiconductor device 2 is bonded onto the mounting substrate 30 without involving melting of the solder balls 18.

Note that, instead of the epoxy thermosetting resin, an Ag paste, a DAF (die attach film; to be described later in a modification), a UV (ultraviolet) curable resin, or the like may be used as the adhesive material 31, and the adhesive material 31 is not limited to a specific kind.

At this time, the solder balls 18 provided on the electrode pattern 17 of the mounting substrate 30 are brought into contact with the external electrodes 16 of the semiconductor device 2. In order to obtain this contact, the size of the solder balls 18 is set as required. In the semiconductor device 2 of this embodiment, the diameter of the through electrodes 14 is about 20 μm to about 120 μm, the positional accuracy upon mounting the semiconductor device 2 is about ±25 μm, and the thickness of the semiconductor device 2 is about 300 μm. The diameter of the solder balls 18 is therefore preferably about 100 μm to about 300 μm. However, the invention is not limited to this. The solder balls 18 may have any size as long as the external electrodes 16 of the semiconductor device 2 contact the solder balls 18 on the mounting substrate 30.

The mounting substrate 30 having the semiconductor device 2 attached thereto is then heated to the melting point of the solder balls 18. As a result, the external electrodes 16 exposed to the side (cutting surface 15) of the semiconductor device 2 are electrically connected with the electrode pattern 17 on the mounting substrate 30 by the solder balls 18. This state is shown in FIG. 4D. Electric connection is therefore obtained from the electrode pattern 17 of the mounting substrate 30 through the solder balls 18 to the external electrodes 16, from the external electrodes 16 through the through electrodes 14 to the electrode pads 12, and from the electrode pads 12 to the elements and the like provided in the active region 11. The external electrodes 16 are not exposed to the back surface of the semiconductor device 2 but to the cutting surface 15. This structure enables a mounting method in which the back surface of the semiconductor device 2 is directly attached to the mounting substrate 30.

In the state of FIG. 4D, the back surface of the semiconductor device 2 is bonded on the mounting substrate 30 by the adhesive material 31. A high parallelism of at most about 5 μm to about 10 μm can therefore be obtained between the mounting substrate 30 and the semiconductor device 2.

Moreover, since the semiconductor device 2 is mounted onto the mounting substrate 30 only through the adhesive material 31, the mounting height H from the surface of the mounting substrate 30 to the top surface of the semiconductor device 2 (the applied thickness of the adhesive material 31 and the thickness of the semiconductor device 2) can be lowered. For example, the applied thickness of the adhesive material 31 is about 5 μm to about 40 μm, which is a required mounting height in addition to the thickness of the semiconductor device 2.

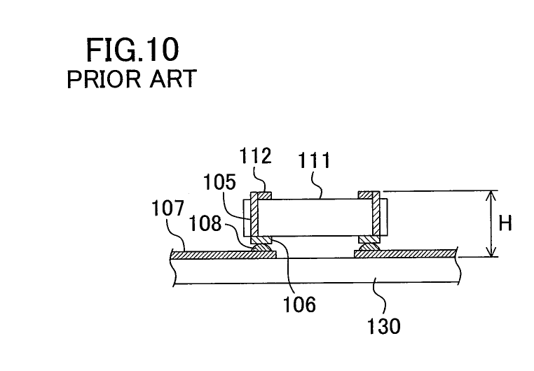

In the mounting method using the conventional semiconductor device and solder balls (see FIG. 10), a mounting height of about 80 μm to about 100 μm (the sum of the thickness of the conductor pattern on the mounting substrate 130, the thickness of the conductor pattern on the back surface of the semiconductor device 102, and the thickness of the solder bumps 108) is required in addition to the thickness of the semiconductor device 102. It can be seen that this embodiment obviously implements reduction in mounting height H.

Unlike the underfill technology, the step of injecting a resin between the semiconductor device and the mounting substrate by using capillarity is not required. Increase in manufacturing cost and manufacturing time can therefore be avoided.

(Modification)

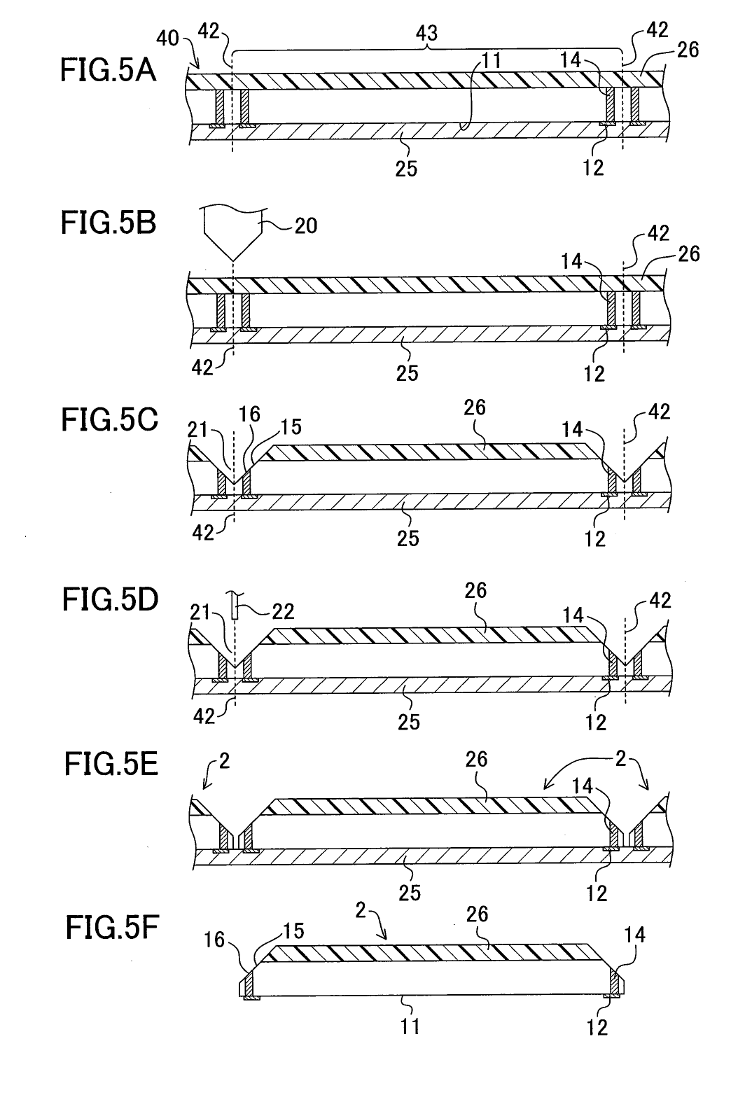

Hereinafter, a modification of the first embodiment will be described with reference to the figures. A method using a thermosetting material such as a DAF (die attach film) to mount the semiconductor device 2 is described in this modification. FIGS. 5A through 5F are diagrams illustrating the modification.

A DAF is typically attached in the state of a semiconductor wafer. A method using a DAF could not be applied to a conventional semiconductor device having through electrodes because the DAF covers the through electrodes. As described below, however, the method using a DAF is applicable to the semiconductor device of the first embodiment.

First, a DAF 26 is attached to the back surface of the semiconductor wafer 40 having the through electrodes 14 and the electrode pads 12 as shown in FIGS. 2A and 2B in the first embodiment. Moreover, the front surface of the semiconductor wafer 40 is attached to the dicing sheet 25 with the DAF 26 side of the semiconductor wafer 40 facing upward. This state is shown in FIG. 5A. FIG. 5A is different from FIG. 3A of the first embodiment in the presence of the DAF 26 attached to the back surface of the semiconductor wafer 40.

Next, the positions of the through electrodes 14 of the semiconductor wafer 40 are detected through the DAF 26 and recognized as dividing positions. When the DAF 26 is made of a light transmitting material, the positions of the through electrodes 14 can be detected by visible light. When the DAF 26 is made of an opaque material, the positions of the through holes 14 are detected by using infrared rays, X rays, or the like.

As shown in FIGS. 5B and 5C, the DAF 26 and the semiconductor wafer 40 are cut by using the dicing blade 20 having a V-shaped tip, whereby the groove portion 21 is formed. The cutting surface 15 is thus formed in each chip region 43, and the through electrodes 14 are exposed to the cutting surface 15 as the external electrodes 16. This step is the same as that described in the first embodiment with reference to FIGS. 3B and 3C except that the DAF 26 on the back surface of the semiconductor wafer 40 is cut.

As shown in FIGS. 5D and 5E, the semiconductor wafer 40 is divided into individual chip regions 43 as semiconductor devices 2 by using the dicing blade 22 having a narrower width than that of the dicing blade 20. Finally, as shown in FIG. 5F, the dicing sheet 25 is peeled and the semiconductor devices 2 are obtained.

The semiconductor device 2 thus manufactured is different from that of the first embodiment only in that the DAF 26 is attached to the back surface of the semiconductor wafer 40. Note that, although the DAF 26 is once attached to the through electrodes 14 (FIG. 5A), the DAF 26 is cut and removed later (FIG. 5C). The method using the DAF 26 is thus applicable to the semiconductor device of the first embodiment.

A mounting method of the semiconductor device 2 having the DAF 26 attached thereto is the same as the mounting method of the first embodiment shown in FIGS. 4A through 4D except that the DAF 26 is used for adhesion instead of the adhesive material 31 applied to the mounting substrate 30.

As has been described above, in this modification, the effect of reducing the mounting height H and the effect of increasing the parallelism can be implemented, and the method using the DAF can be applied.

### Second Embodiment

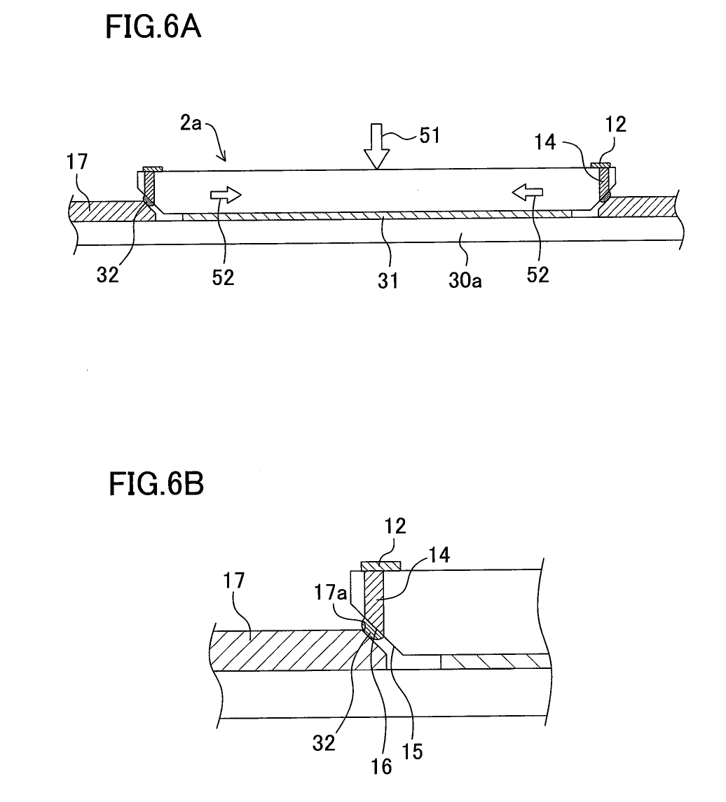

Hereinafter, a semiconductor device 2a and a mounting method thereof according to a second embodiment of the invention will be described with reference to the figures. FIG. 6A is a cross-sectional view of the semiconductor device 2a of the second embodiment mounted on a mounting substrate 30a, and FIG. 6B is an enlarged view of a region around a peripheral portion of the semiconductor device 2a in FIG. 6A.

As shown in FIGS. 6A and 6B, the semiconductor device 2a further includes bumps 32 on external electrodes 16 in addition to the structure of the semiconductor device 2 of the first embodiment. The bumps 32 are made of a conductive metal material such as solder bumps, Au bumps, Au stat bumps, and Cu bumps and protrude from the surface of the external electrodes 16. Other elements are denoted with the same reference numerals as those of the semiconductor device 2 and detailed description thereof will be omitted.

An electrode pattern 17 on a mounting substrate 30a has a tilted surface 17a in a region that is in contact with the bumps 32 of the semiconductor device 2a. The tilted surface 17a is tilted according to the cutting surface 15.

When the semiconductor device 2a is mounted, a force 51 is applied to the semiconductor device 2a in a direction vertical to the mounting substrate 30a in order to press the semiconductor device 2a against the mounting substrate 30a. As a result, the bumps 32 on the external electrodes 16 are pressure-welded to the tilted surface 17a of the electrode pattern 17, whereby electric connection can be reliably obtained. Since the cutting surface 15 having the external electrodes 16 and the tilted surface 17a of the electrode pattern 17 are both tilted with respect to the direction of the force 51. A force 52 is therefore applied to the semiconductor device 2a in an inward direction of the semiconductor device 2a. Such a force 52 works on the four sides of the semiconductor device 2a, and the semiconductor device 2a is displaced in a lateral direction until the four sides are balanced and the resultant force in the lateral direction becomes zero. By thus pressing the semiconductor device 2a vertically against the mounting substrate 30a, the semiconductor device 2a can be mounted on the mounting substrate 30a in a self-aligned manner with high positional accuracy.

Note that, as in the first embodiment, the semiconductor device 2a can be bonded to the mounting substrate 30a by using an adhesive material 31 such as an Ag paste, an epoxy resin, and a DFA.

As has been described above, according to the second embodiment, the mounting height H can be reduced and the mounting parallelism can be improved as in the first embodiment. Moreover, the mounting positional accuracy can be easily improved.

### Third Embodiment

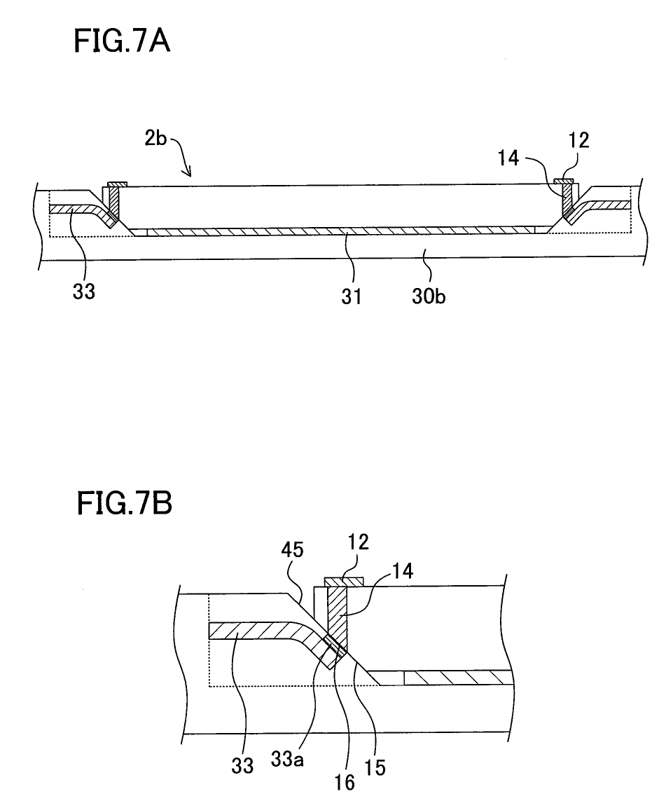

Hereinafter, a semiconductor device 2b and a mounting method thereof according to a third embodiment of the invention will be described with reference to the figures. FIG. 7A is a cross-sectional view of the semiconductor device 2b of the third embodiment mounted on a mounting substrate 30b, and FIG. 7B is an enlarged view of a region around a peripheral portion of the semiconductor device 2b in FIG. 7A.

Since the semiconductor device 2b is the same as the semiconductor device 2 of the first embodiment, detailed description thereof will be omitted.

As shown in FIGS. 7A and 7B, the mounting substrate 30b includes a tilted surface 45 that is in contact with a cutting surface 15 of the semiconductor device 2b, and an electrode pattern 33 that is electrically connected to external electrodes 16. The electrode pattern 33 is made of a material having a spring property (an elastic deformation region). The material may be a metal material such as Cu and spring steel, or a conductive material having an elastic deformation region. Projections 33a smaller in size than the external electrodes 16 are provided in a contact portion of the electrode pattern 33 with the external electrodes 16.

When the semiconductor device 2b is mounted on the mounting substrate 30b, the projections 33a of the electrode pattern 33 having a spring property are pressure-welded to the external electrodes 16, whereby electric connection can be reliably obtained. Even if the mounted position of the semiconductor device 2b is displaced from a designed position, the electrode pattern 33 having a spring property is deformed and electric connection is assured if the displacement is small.

Moreover, by pressing the semiconductor device 2b vertically against the mounting substrate 30b with the tilted surface 45 and the cutting surface 15 being in contact with each other, the positional accuracy can be improved in a self-aligned manner as in the second embodiment.

An adhesive material 31 for bonding the semiconductor device 2b to the mounting substrate 30b is the same as that in the first embodiment.

Note that an example in which the taper shape having the cutting surface 15 is provided on the four sides of the semiconductor device is described above. However, the invention is not limited to this structure, and the taper shape need only be provided on at least one side of the semiconductor device.

As has been described above, the use of the semiconductor device 2b and the mounting substrate 30b according to the second embodiment enables reduction in mounting height H and improvement in mounting parallelism, and also implements improvement in mounting positional accuracy and improvement in reliability of electric connection.

What is claimed is:

1. A semiconductor device, comprising:
a semiconductor substrate having an active region on a surface thereof;
at least one electrode pad provided in a peripheral portion of the surface of the semiconductor substrate; and
a through electrode extending through the semiconductor substrate and connected to the electrode pad, wherein a taper is provided on at least one side of the semiconductor substrate, whereby a portion of the through electrode which is exposed to a side of the semiconductor substrate serves as an external electrode.

2. The semiconductor device according to claim 1, wherein the taper provided on at least one side of the semiconductor substrate has a cutting surface formed by cutting the peripheral portion from a back surface thereof, and the through electrode extends from the electrode pad to the cutting surface, and a portion of the through electrode which is exposed to the cutting surface serves as the external electrode.

3. The semiconductor device according to claim 1, wherein a projection made of a conductive material is provided on the external electrode.

4. A method for mounting the semiconductor device according to claim 1 on a mounting substrate, comprising the steps of:
fixing a back surface of the semiconductor device to the mounting substrate; and
electrically connecting the external electrode exposed to a side of the semiconductor device with a substrate electrode provided on the mounting substrate.

5. The method according to claim 4, wherein the substrate electrode has an elastic property.

6. The method according to claim 4, wherein an electrode projection that is smaller than the external electrode of the semiconductor device is provided on the substrate electrode, and the substrate electrode and the through electrode are electrically connected to each other through the electrode projection.

7. A method for manufacturing a semiconductor device, comprising the steps of:
(a) preparing a semiconductor wafer having a plurality of chip regions that are to be diced into individual semiconductor devices;
(b) in each of the plurality of chip regions, providing at least one electrode pad on a peripheral portion of a surface having an active region and providing a through electrode extending from a back surface of the semiconductor wafer to the electrode pad;
(c) after the step (b), cutting a peripheral portion of the back surface in each of the plurality of chip regions to expose the through electrode to a side of the chip region so that the exposed portion serves as an external electrode; and
(d) after the step (c), the plurality of chip regions are diced into individual semiconductor devices.

8. The method according to claim 7, wherein the step (c) is performed by forming, in a portion including a dividing line between adjacent chip regions, a groove portion having a V-shaped cross section from the back surface of the semiconductor wafer, and the dicing is performed along the groove portion in the step (d).

9. The method according to claim 7, further comprising the step of, after the step (c), providing a projection made of a conductive material on the external electrode.
